(19) United States
(12) Patent Application Publication
(10) Pub. No.: US 2010/0200895 A1
(43) Pub. Date: Aug. 12, 2010

(54) UNIT PIXEL IMPROVING IMAGE SENSITIVITY AND DYNAMIC RANGE

(75) Inventor: Do-Young Lee, Seongnam-si (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/671,249

(22) PCT Filed: Aug. 4, 2008
(86) PCT No.: PCT/KR2008/004507

§ 371 Date: Jan. 29, 2010

(30) Foreign Application Priority Data
Aug. 9, 2007 (KR) 10-2007-0080164

(51) Int. Cl. H01L 27/146; H01L 31/18

(52) U.S. Cl. 257/225; 438/59; 257/E27.132; 257/E31.097

(57) ABSTRACT

Provided are a unit pixel for improving sensitivity in low illumination conditions and a method of manufacturing the unit pixel. The unit pixel includes: a photodiode generating image charges corresponding to an image signal; a transfer transistor transferring the image charges to a floating diffusion area; and a reset transistor having a terminal connected to the floating diffusion area and the other terminal applied with a power supply, wherein concentration of impurity ions implanted into the floating diffusion area is lower than concentration of impurity ions implanted into a diffusion area of the reset transistor applied with the power supply.

### BACKGROUND OF THE INVENTION

1. Field of the Invention

The present invention relates to a unit pixel, and more particularly, to a unit pixel for improving sensitivity in low illumination conditions and increasing a dynamic range.

2. Description of the Related Art

FIG. 1 is a circuit diagram of a unit pixel included in an image sensor.

Referring to FIG. 1, the unit pixel includes a photodiode PD and an image signal conversion circuit. The image signal conversion signal includes a transfer transistor M1, a reset transistor M2, a conversion transistor M3, and a selection transistor M4.

The photodiode PD generates image charges corresponding to an image signal. The image charges are transferred to a floating diffusion area FD through the transfer transistor M1 that is switched on or off in response to a transfer control signal Tx.

The reset transistor M2 resets the floating diffusion area FD

The conversion transistor M3 generates a conversion voltage corresponding to charges accumulated into the floating diffusion area FD. The conversion voltage is output through the selection transistor M4 that is switched on or off in response to a selection control signal Sx.

The floating diffusion area FD may be implemented as a capacitor as a modeling. The total capacitance C_{T} of the floating diffusion area FD may be a sum of:

1. a junction capacitance between the floating diffusion area FD and a substrate;

2. a gate capacitance; and

3. an overlap capacitance.

Since the floating diffusion area FD has an N-type in a case where the substrate is assumed to have a P-type, a PN junction structure is formed between the floating diffusion area FD and the substrate. The junction capacitance between the floating diffusion area and the substrate means junction capacitance caused by the floating diffusion area and the substrate that serve as two electrodes and a depletion area formed between the two electrodes.

The junction capacitance described later includes capacitance between the floating diffusion area FD and a side wall.

The gate capacitance means gate capacitance formed by the floating diffusion area FD, a gate oxide of the conversion transistor M3, and a bulk of the conversion transistor M3. The overlap capacitance denotes capacitance caused by a portion where gate terminals of the two transistors M1 and M2 and the floating diffusion area FD overlap each other with the gate oxides of the transfer transistor M1 and the reset transistor M2 interposed therebetween.

Here, the gate capacitance and the overlap capacitance may have fixed values as a manufacturing process is completed. However, the junction capacitance has a variable value according to a voltage level dropped in the floating diffusion area FD.

The capacitance C of the capacitor may be simply represented as Equation 1.

$$C = \frac{{ɛ}_{ox} A}{d} \qquad [ Equation 1 ]$$

Here, Eₒₓ denotes permittivity of a dielectric material for forming the capacitor, A denotes an area of the dielectric material, and d denotes a distance between two electrodes or a thickness of the dielectric material.

In the case of the junction capacitor, the permittivity and the area of the dielectric material are fixed as the manufacturing process is completed. However, since a width of the depletion area that becomes the dielectric material is changed according to a voltage applied to the two electrodes of the junction capacitor, the junction capacitance is also changed. For example, if the voltage applied to the substrate is fixed, in a case where a voltage applied to the floating diffusion area FD that has the N-type material is increased in a positive direction, a reverse bias is applied to the depletion area between the P-type substrate made of the P-type material and the floating diffusion area made of the N-type material, so that the width of the depletion area is increased. This causes increase in the thickness d of the dielectric material in Equation 1, so that the junction capacitance is decreased.

In order to generate the floating diffusion area,

1. the floating diffusion area is defined by using a mask,

2. impurity ions are implanted into the portion defined as the floating diffusion area, and

3. annealing is performed to uniformly diffuse the implanted impurities.

Here, according to concentration of the impurity ions implanted into the floating diffusion area, the capacitance of the overlap capacitor is changed.

Specifically, if an enough annealing time is provided, as the concentration of the impurity ions implanted into the floating diffusion area is increased, a width of diffusing the impurity ions in vertical and horizontal directions is increased, and eventually, the area where the floating diffusion area FD and the gate oxides of the transfer and reset transistors M1 and M2 overlap increases, so that the overlap capacitance is increased. Therefore, when the manufacturing process is completed, the capacitance of the overlap capacitor is fixed. However, the total capacitance is changed according to the concentration of impurities implanted into the floating diffusion area FD.

Here, a phenomenon in which the capacitance of the overlap capacitor is fixed generally occurs when the concentration of the impurity ions implanted into the diffusion area exceeds a predetermined limit. Therefore, in a case where the concentration does not reach the predetermined limit, the capacitance of the overlap capacitor is changed according to the voltage applied to the both electrodes of the overlap capacitor. This will be described later.

As described above, the transfer and reset transistors M1 and M2 are switched on or off by the transfer and reset control signals Tx and Rx, respectively. Here, noise occurs in the floating diffusion area FD as the two transistors M1 and M2 are turned on or off, and this is referred to as switching noise. An amount of the switching noise is in proportion to the capacitance of the overlap capacitor, so that in order to reduce the switching noise, the capacitance of the overlap capacitor has to be reduced.

As described above, since the junction capacitor is changed in proportion to the voltage value dropped in the floating diffusion area FD, there is a problem in that a dynamic range and low illumination conditions of the image sensor including the pixel having those electrical characteristics may be reduced.

### SUMMARY OF THE INVENTION

The present invention provides a unit pixel for improving low illumination conditions and increasing a dynamic range.

The present invention also provides a method of manufacturing a unit pixel for improving low illumination conditions and increasing a dynamic range.

According to an aspect of the present invention, there is provided a unit pixel including: a photodiode generating image charges corresponding to an image signal; a transfer transistor transferring the image charges to a floating diffusion area; and a reset transistor having a terminal connected to the floating diffusion area and the other terminal applied with a power supply, wherein concentration of impurity ions implanted into the floating diffusion area is lower than concentration of impurity ions implanted into a diffusion area of the reset transistor applied with the power supply.

According to another aspect of the present invention, there is provided a unit pixel including: one or more photodiodes generating image charges corresponding to an image signal; one or more transfer transistors connected to the corresponding one or more photodiodes to transfer the image charges to a common floating diffusion area; and a reset transistor having a terminal connected to the common floating diffusion area and the other terminal applied with a power supply, wherein concentration of impurity ions implanted into the common floating diffusion area is lower than concentration of impurity ions implanted into a diffusion area of the reset transistor applied with the power supply.

According to another aspect of the present invention, there is provided a method of manufacturing a unit pixel which includes a photodiode and an image signal conversion circuit for converting an image signal into an electrical signal, wherein the method uses: a first mask for defining a floating diffusion area; and a second mask for defining remaining diffusion areas excluding the floating diffusion area from diffusion areas included in the image signal conversion circuit, and wherein the method includes steps of: implanting N (N is an integer) impurity ions into an area defined as the first mask; and implanting M (M is an integer) impurity ions into an area defined as the second mask.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a unit pixel included in an image sensor;

FIG. 2 illustrates a layout of a general unit pixel;

FIG. 3 is a cross-sectional view of the layout illustrated in FIG. 2 taken along line AA';

FIG. 4 illustrates a measurement condition of measuring voltage characteristics of a positive-negative (PN) junction applied with a reverse bias;

FIG. 5 illustrates two concentrations of the impurity ions implanted into an N-type diffusion area illustrated in FIG. 4 and output voltages changed according to the reverse bias voltage;

FIG. 6 illustrates a change in junction capacitance of the PN junction in the voltage measurement condition illustrated in FIG. 4; and

FIG. 7 illustrates capacitance of a modeling capacitor of a floating diffusion area according to a voltage dropped in the floating diffusion area.

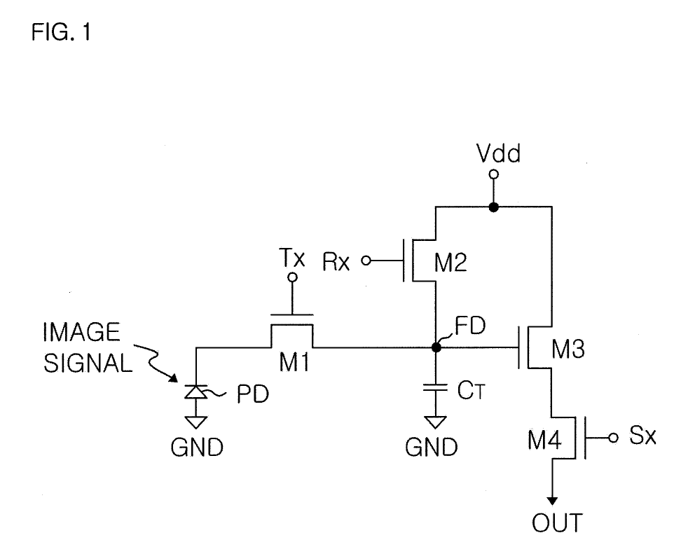

### DETAILED DESCRIPTION OF THE INVENTION

Exemplary embodiments of the present invention will now be described in detail with reference to the accompanying drawings.

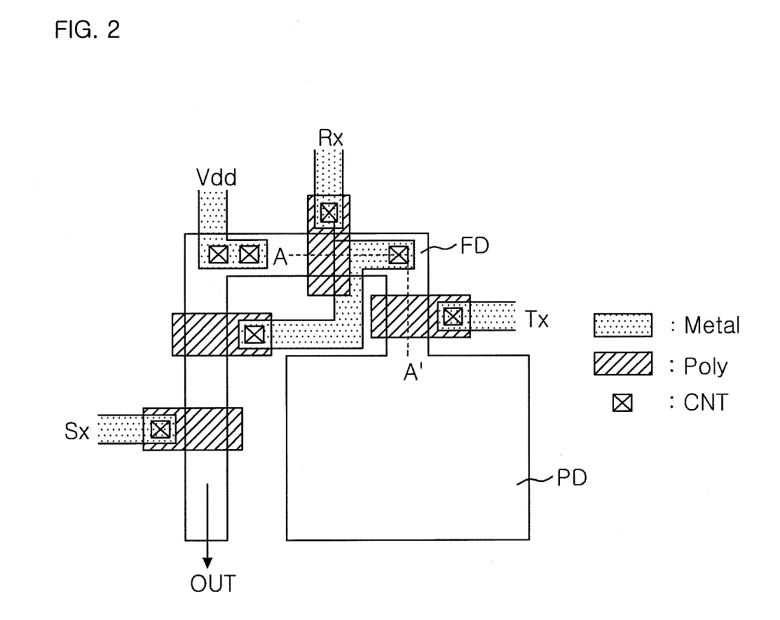

FIG. 2 illustrates a layout of a general unit pixel.

Referring to FIG. 2, gate terminals are illustrated as hatched rectangles and may be made of polycrystalline silicon.

Metal lines are illustrated as rectangles filled with dots, and the metal lines, the gate terminals, and diffusion areas are electrically connected through contacts illustrated as squares having X marks.

Referring to FIG. 2, the unit pixel includes a photodiode PD and an image signal conversion circuit. The image signal conversion circuit includes a transfer transistor, a reset transistor, a conversion transistor, and a selection transistor.

The transfer transistor includes a photodiode area PD that serves as a drain terminal and a source terminal, a floating diffusion area FD, and a gate terminal applied with a transfer control signal Tx. The reset transistor includes the floating diffusion area FD that serves as a drain terminal and a source terminal, a diffusion area applied with a source voltage V_{dd}, and a gate terminal applied with a reset control signal Rx. The conversion transistor includes a diffusion area that serves as a drain terminal or a source terminal and is applied with the source voltage Vdd and a gate applied with a voltage of the floating diffusion area FD. The selection transistor includes a diffusion area having a terminal commonly connected to the other terminal of the conversion transistor and the other terminal for outputting a conversion voltage OUT and a gate terminal applied with a selection control signal Sx.

Here, irrespective of types of transistors, the terminal and the other terminal are referred to as the drain terminal and the source terminal, respectively. The drain terminal and the source terminal of a P-type metal-oxide-semiconductor (MOS) transistor are switched with each other in an N-type MOS transistor. Here, this will be understood by those skilled in the art and not be described in detail.

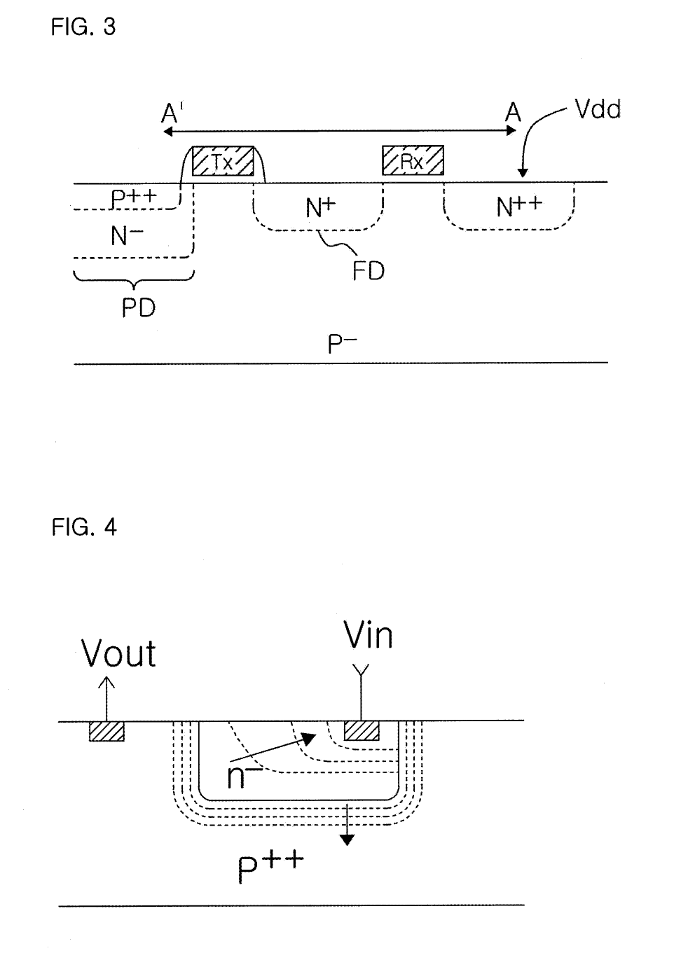

FIG. 3 is a cross-sectional view of the layout illustrated in FIG. 2 taken along line AA′.

Referring to FIG. 3, a photodiode PD is formed at a left surface of a P⁻ substrate, and a gate terminal Tx of a transfer transistor is formed between the photodiode PD and an N⁺ floating diffusion area FD. A gate terminal Rx of a reset transistor is formed between the floating diffusion area FD and a diffusion area applied with a source voltage Vdd. Here, the two gate terminals Tx and Rx are disposed on an upper surface of a substrate. Although not shown in FIG. 3, an insulating material exists between the gate terminals Rx and Tx and the substrate, and electrical characteristics of the insulating material determines a rated voltage of a MOS transistor in addition to a threshold voltage of the MOS transistor. In addition, a thickness of the insulating material has to have a fixed value. Therefore, the insulating material may be formed by performing thermal growth on silicon dioxide.

Referring to FIG. 3, the floating diffusion area FD is denoted by N⁺, and the right diffusion area of the reset transistor Rx is denoted by N⁺⁺. This means that the number of implanted impurity ions in the N⁺ is smaller than that in the N⁺⁺. For example, the number of impurity ions implanted into the N⁺⁺ may be about 10²²/Cm³, and the number of impurity ions implanted into the N⁺ may be about from 10¹³ to 10¹⁹/Cm³ depending on areas, so that the effect of the present invention can be obtained.

A conventional floating diffusion area and remaining diffusion areas are simultaneously defined by a signal mask and formed in a single impurity ion implantation process. Therefore, concentration of the impurity ions implanted into the floating diffusion area FD and concentration of the impurity ions implanted into the remaining diffusion areas for forming the drain and source areas of transistors are equal to each other.

According to an aspect of the present invention, the concentration of the impurity ions implanted into the floating diffusion area FD is decreased to be lower than the concentration of the impurity ions implanted into the diffusion areas for forming the drain and source areas of the MOS transistors excluding the floating diffusion area, in order to improve low illumination conditions and increase a dynamic range.

Now, a physical meaning of lowering the concentration of the impurities in the floating diffusion area FD is described.

FIG. 4 illustrates a measurement condition of measuring voltage characteristics of a PN junction applied with a reverse bias.

Referring to FIG. 4, a condition for measuring voltage response (referred to as Vₒᵤₜ) characteristics in the P-type area as a voltage Vᵢₙ applied to the N-type area of the PN function is illustrated. Dotted contour lines around the PN junction represent boundary surfaces of the depletion area of the PN junction. Here, since the N-type area is denoted by N⁻ and the P-type area is denoted by P⁺⁺, it can be seen that the concentration of the impurity ions implanted into the N-type area is lower than the concentration of the impurity ions implanted into the P-type area.

An arrow illustrated in FIG. 4 means a movement direction of the boundary surfaces of the depletion area when the reverse bias voltage is increased. As the voltage Vᵢₙ is increased, the boundary lines of the depletion area of the P-type area and the boundary lines of the depletion area of the N-type area become far from the PN junction portion. The width of the depletion area is increased as the reverse bias voltage applied to the depletion area of the PN junction is increased. Here, the width of the depletion area having the relatively smaller number of the implanted impurity ions from among the P-type and N-type diffusion areas is increased at higher speed. The theoretical background of this physical phenomenon is well known, so that a detailed description thereof is omitted. In FIG. 4, in order to represent the aforementioned physical phenomenon, it is illustrated that intervals between the boundary lines of the depletion area of the N-type area are larger than intervals between the boundary lines of the depletion area of the P-type area.

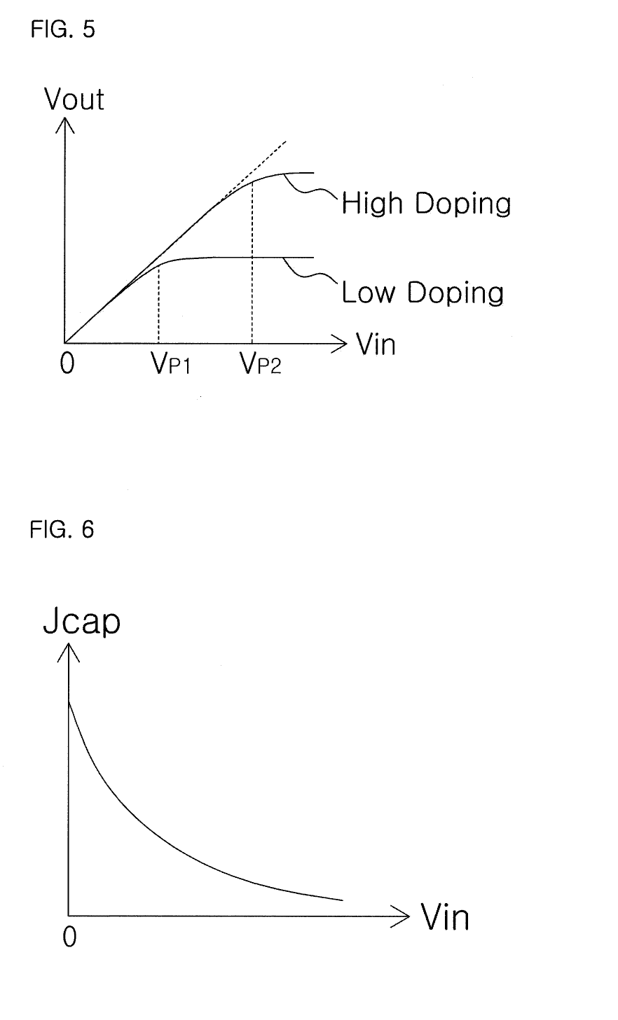

FIG. 5 illustrates two concentrations of the impurity ions implanted into the N-type diffusion area illustrated in FIG. 4 and output voltages changed according to the reverse bias voltage.

In a case where the concentration of the impurities implanted into the N-type diffusion area is relative low (referred to as low doping), until the reverse bias voltage Vᵢₙ applied to the N-type diffusion area is increased to a first limit Vₚ₁, the output voltage Vₒᵤₜ detected in the P-type diffusion area is increased to have a predetermined gradient. However, after the reverse bias voltage Vᵢₙ is increased to be higher than the first limit Vₚ₁, the output voltage Vₒᵤₜ is not increased. In a case where the concentration of the impurities implanted into the N-type diffusion area is relatively high (referred to as high doping), until the reverse bias voltage Vᵢₙ is increased to a second limit Vₚ₂, the output voltage Vₒᵤₜ is increased to have a predetermined gradient. However, after the reverse bias voltage Vᵢₙ is higher than the second limit Vₚ₂, the output voltage Vₒᵤₜ is not increased. Here, the second limit Vₚ₂ has a higher voltage level than the first limit Vₚ₁.

As described above, after the reverse bias voltage Vᵢₙ applied to the N-type diffusion area is increased to be higher than the predetermined limit, the output voltage Vₒᵤₜ cannot be increased. This is because the entire N-type diffusion area becomes the depletion area since the reverse bias voltage Vᵢₙ reaches the limit voltage, and the N-type diffusion area in this case is referred to as pinning. In the pinning area, there is little charge movement. Therefore, although the voltage level of the reverse bias voltage Vᵢₙ is increased, current does not flow between the N-type and P-type diffusion areas. Therefore, the increase in the reverse bias voltage Vᵢₙ cannot exert any influence on the output terminal, so that the voltage of the output terminal Vₒᵤₜ cannot be increased.

FIG. 6 illustrates a change in the junction capacitance of the PN junction in the voltage measurement condition illustrated in FIG. 4.

The junction capacitance J_{cap} illustrated in FIG. 6 is the capacitance of the junction capacitor formed by the P-type diffusion area of the PN junction, the depletion area, and the N-type diffusion area. As the reverse bias voltage Vᵢₙ applied to the N-type diffusion area is increased, the thickness of the depletion area is increased. Referring to Equation 1, as the thickness d of the insulating material existing between the both terminals of the capacitor is increased, the capacitance is decreased.

As described above, by pinning the floating diffusion area FD, two effects can be obtained.

First, the thickness of the insulating material of the overlap capacitor is significantly increased, so that the overlap capacitance is minimized, and the switching noise components can be significantly suppressed.

Second, in a case where the voltage applied to the floating diffusion area is high, the junction capacitance between the substrate and the floating diffusion area can be minimized.

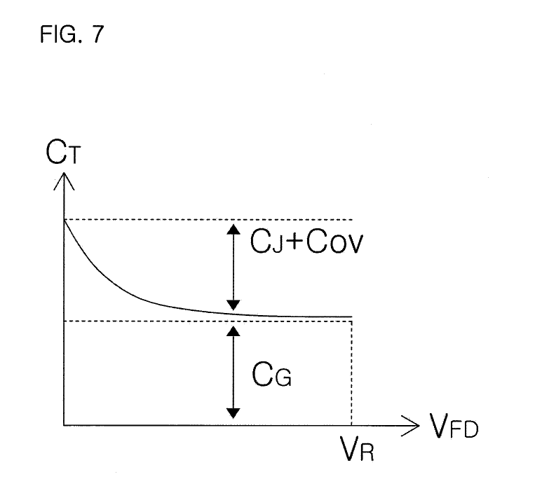

FIG. 7 illustrates the capacitance of the modeling capacitor of the floating diffusion area according to the voltage dropped in the floating diffusion area.

Referring to FIG. 7, the capacitance C_{T} of the modeling capacitor of the floating diffusion area FD may be represented as a sum of the gate capacitance C_{G}, the junction capacitance C_{J}, and the overlap capacitance C_{OV}. It is assumed that the voltage level V_{FD} of the floating diffusion area FD when reset is called a reset voltage V_{R}[V].

When an image signal applied to the photodiode is weak (referred to as low illumination conditions), a small amount of image charges are generated by the photodiode. Even if the small amount of image charges is transferred to the floating diffusion area FD, the transferred image charges cannot exert any influence on the voltage of the floating diffusion area FD. Therefore, the voltage level V_{FD} of the floating diffusion area FD is not substantially changed from the reset voltage V_{R}[V]. In a case where the voltage level of the floating diffusion area FD is V_{R}[V], the junction capacitance C_{J} and the overlap capacitance C_{OV} approach to a value of 0, so that the modeling capacitance C_{T} of the floating diffusion area depends on the gate capacitance C_{G}. As described above, only the minimum capacitance exists for the image signal in the low illumination conditions, and in this case, the switching noise components can be minimized.

When illuminance increases and an image signal with high illuminance is applied, a large amount of image charges corresponding to the high illuminance are generated and transferred to the floating diffusion area FD, and accordingly, the voltage level V_{FD} of the floating diffusion area FD is also decreased. Since the junction capacitance C_{J} and the overlap capacitance C_{OV} are additionally included in the gate capacitance C_{G} as the voltage dropped in the floating diffusion area FD is decreased, the modeling capacitance C_{T} of the floating diffusion area FD may have an increased amount of the switching noise components. However, in this case, the strength of the image signal is significantly higher than the switching noise, so that the switching noise cannot seriously affect the conversion of the image signal.

Therefore, as described above, by decreasing the pining voltage of the floating diffusion area FD, the sensitivity of the image signal in the low illumination conditions can be improved. The improvement in the sensitivity of the image signal in the low illumination conditions means increase in the dynamic range of the image sensor using the pixel.

In the aforementioned description, the unit pixel has a construction including a single photodiode and a single image signal conversion circuit. However, a separation type unit pixel for implementing the photodiode and the transfer transistor in a chip and the remaining transistors in the other chip is proposed. In addition, in a case of the separation type unit pixel, a technique of connecting a plurality of photodiodes and corresponding transfer transistors to a single common floating diffusion area and performing a switching operation on the transfer transistor in a time division method to be used in order to decrease an area of a chip or increase an area allocated to the photodiodes has been proposed.

If the point according to the present invention can be understood, applying the point according to the present invention to the separation type unit pixel is easy, so that a detailed description thereof is omitted.

There are various methods of manufacturing the aforementioned unit pixel. An example of the methods of implementing the unit pixel by using two masks is explained.

In order to manufacture the unit pixel according to the present invention, other processes are applied according to general standard processes. However, particularly, a first mask for defining the floating diffusion area and a second mask for defining remaining diffusion areas excluding the floating diffusion area from the diffusion areas included in the image signal conversion circuit are used.

Here, into an area defined as the first mask, N (N is an integer) impurity ions are implanted, and into an area defined as the second mask, M (M is an integer) impurity ions are implanted. The M is larger than the N. The N may have a value of, for example, from 10¹³/Cm³ to 10¹⁹/Cm³.

The present invention has advantages in that low illumination conditions of the unit pixel are improved and a dynamic range thereof is increased.

While the present invention has been shown and described in connection with the exemplary embodiments, it will be apparent to those skilled in the art that modifications and variations can be made without departing from the spirit and scope of the invention as defined by the appended claims.

What is claimed is:

1. A unit pixel comprising:
a photodiode generating image charges corresponding to an image signal;
a transfer transistor transferring the image charges to a floating diffusion area; and
a reset transistor having a terminal connected to the floating diffusion area and the other terminal applied with a power supply,
wherein concentration of impurity ions implanted into the floating diffusion area is lower than concentration of impurity ions implanted into a diffusion area of the reset transistor applied with the power supply.

2. The unit pixel of claim 1, the number of the impurity ions implanted into the floating diffusion area has a value of from 10¹⁷/Cm³ to 10²⁰/Cm³.

3. A unit pixel comprising:
one or more photodiodes generating image charges corresponding to an image signal;
one or more transfer transistors connected to the corresponding one or more photodiodes to transfer the image charges to a common floating diffusion area; and
a reset transistor having a terminal connected to the common floating diffusion area and the other terminal applied with a power supply,
wherein concentration of impurity ions implanted into the common floating diffusion area is lower than concentration of impurity ions implanted into a diffusion area of the reset transistor applied with the power supply.

4. The unit pixel of claim 1, wherein the number of the impurity ions implanted into the floating diffusion area has a value of from 10¹⁷/Cm³ to 10²⁰/Cm³.

5. A method of manufacturing a unit pixel which includes a photodiode and an image signal conversion circuit for converting an image signal into an electrical signal,
wherein the method uses:
a first mask for defining a floating diffusion area; and
a second mask for defining remaining diffusion areas excluding the floating diffusion area from diffusion areas included in the image signal conversion circuit, and
wherein the method comprises steps of:
implanting N (N is an integer) impurity ions into an area defined as the first mask; and
implanting M (M is an integer) impurity ions into an area defined as the second mask.

6. The method of claim 5, wherein the M is larger than the N.

7. The method of claim 5, wherein the N has a value of from 10¹³/Cm³ to 10¹⁹/Cm³.
